(19) United States
(12) Patent Application Publication
(10) Pub. No.: US 2018/0231489 A1
(43) Pub. Date: Aug. 16, 2018

(54) BIOSENSOR TEST STRIP AND ITS ETCHANT-FREE FABRICATION METHOD

(71) Applicant: CHEESHIN TECHNOLOGY CO., LTD., Miaoli County (TW)

(72) Inventors: Kuo-Chen HSU, Miaoli County (TW); Chien-Hao SU, Miaoli County (TW)

(21) Appl. No.: 15/492,581

(22) Filed: Apr. 20, 2017

(30) Foreign Application Priority Data
Feb. 10, 2017 (TW) 106104391

(51) Int. Cl. G01N 27/327; C23C 14/20; C23C 14/04; C23C 14/58; B41F 15/08; B41F 17/00

(52) U.S. Cl. CPC G01N 27/3272; C23C 14/205; B41F 17/006; C23C 14/5873; B41F 15/0895; C23C 14/042

(57) ABSTRACT

A biosensor test strip made in the process without the use of an etchant and its etchant-free fabrication method. A patterned stripping layer is formed onto a substrate and is comprised of a masking region and a hollow region, wherein the hollow region defines a wiring pattern. A metallic film is sputtered onto the masking region of the patterned stripping layer as well as the substrate below the hollow region. The patterned stripping layer is washed off by a non-etchant liquid to remove the masking region and the metallic film thereon. The metallic film on the substrate is remained to form a detection line corresponding to the wiring pattern. A pad layer and a reacting enzyme are formed respectively on the detection line and the substrate. The present invention employs the non-etchant liquid to conduct a removing process so as to form the detection line.

### FIELD OF THE INVENTION

The present invention relates to a biosensor test strip. It is more particularly related to a biosensor test strip made in the process without the use of an etchant and a method of producing the same.

### BACKGROUND OF THE INVENTION

With the progress of medical treatments, chronic diseases, instead of infectious diseases, gradually become one of the main causes of human deaths. Accordingly, the concept of self-health management turns to be increasingly popular. The relevant health tests conducted in the hospital, however, consume a lot of time and cost. Nowadays, each house is usually equipped with the devices for detecting, testing or collecting the physiological data, such as blood glucose, cholesterol, uric acid, etc. Such devices can perform a fast and easy measurement through biosensor test strips with the reading machines so as to bring people toward a better health management.

The most important component on a biosensor test strip is the electrodes used to perform the test. Through the lithography and etching technology, working electrodes and reference electrodes on the test strip can be formed. The reasons for taking the etching technique in use are because it is with a high production efficiency and the metal being etched off can be recycled for a further use, etc. However, the etching technique is also with the problems of high costs, chemical pollutions and residual etching liquid or etchant. Another fabrication method is described in U.S. Pat. No. 6,662,439, “Laser defined features for patterned laminates and electrodes”, which employs the laser ablation technology to accurately ablate the electrodes on a metallic film. Even though this method can avoid the problem of the residual etching liquid, it still has a low production efficiency and the metal being ablated is not recyclable.

As a result, in the fabrication of the electrodes on the test strip, how to avoid the problems of chemical pollution as well as the residual etching solution and to improve the production efficiency and the recycling rate of the metal has become an important subject in the relevant industrial.

### SUMMARY OF THE INVENTION

The present invention is mainly directed to solve the problems of the chemical pollution as well as the residual etching liquid in the production of the biosensor test trip, the low production efficiency and the low recycling rate of metal.

In order to achieve the above-identified objects, the present invention provides a method for producing a biosensor test strip without the use of any etching liquid, which comprises the steps of:

S1: forming a patterned stripping layer on a substrate, wherein the patterned stripping layer comprises a masking region and a hollow region adjacent to the masking region to expose the substrate, and the hollow region defines a wiring pattern;

S2: sputtering a metallic film onto the masking region of the patterned stripping layer and the substrate below the hollow region;

S3: removing the masking region together with the metallic film thereon through a non-etching liquid miscible with the patterned stripping layer, but leaving the metallic film on the substrate so as to form a detection line corresponding to the wiring pattern of the hollow region, wherein the detection line comprises a working end and a measuring end away from the working end;

S4: forming a pad layer on the detection line and the substrate, wherein the pad layer comprises an opening to expose the working end; and

S5: forming a reacting enzyme in the opening.

In order to achieve the above-identified objects, the present invention further provides a biosensor test strip produced by the steps as listed above.

In summary, the present invention employs the non-etchant liquid to remove the pattered stripping layer, thereby avoiding the chemical contamination caused by the etchant as well as solving the problem of the residual etchant on the biosensor test strip. Through the method provided by the present invention, it can also increase the production efficiency. In addition, the removed metallic film can be reused from the non-etching liquid to reduce the costs.

### BRIEF DESCRIPTION OF THE DRAWINGS

The drawings described herein are for illustration purposes only and are not intended to limit the scope of the present disclosure in any way:

FIG. 1 illustrates a flow chart of the fabrication method according to one preferred embodiment to the present invention.

FIG. 2 is an exploded view of one preferred embodiment to the present inventive biosensor test strip

FIG. 3 is a perspective view according to one preferred embodiment to the present inventive biosensor test strip.

FIGS. 4A to 4C are cross-sectional views taken along the line A-A in FIG. 3, showing sequential steps in the fabrication of the biosensor test strip according to one preferred embodiment to the present invention.

FIG. 5 illustrates a cross-sectional view taken along the line A-A, showing a different formation of the metallic film according to another preferred embodiment to the present invention.

FIG. 6 is an illustrative view of the detection lines arranged in an array form according to one preferred embodiment to the present invention.

### DETAILED DESCRIPTION OF THE PREFERRED EMBODIMENTS

The detailed description and technical contents of the present invention will be described with reference to the accompany drawings as follows:

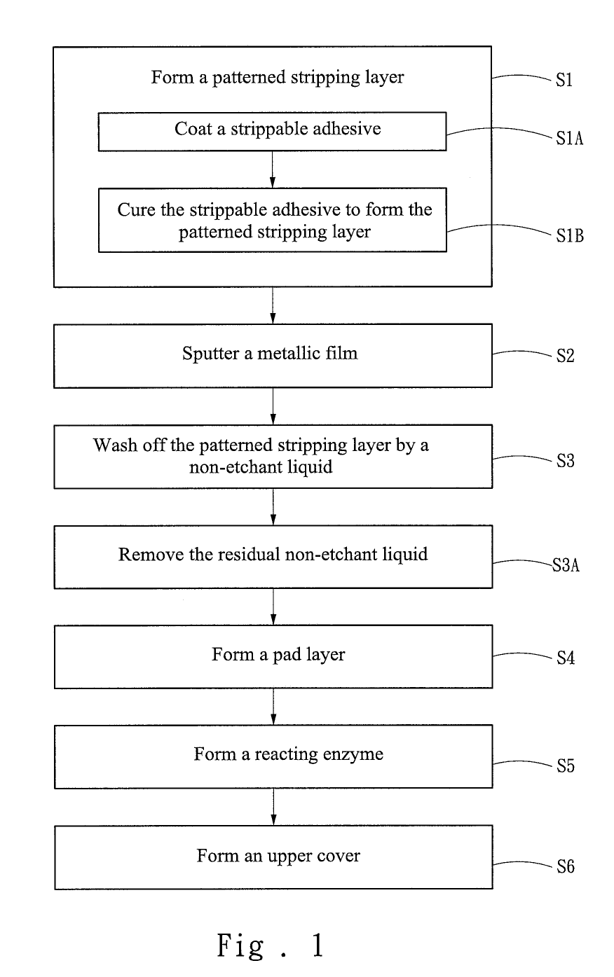

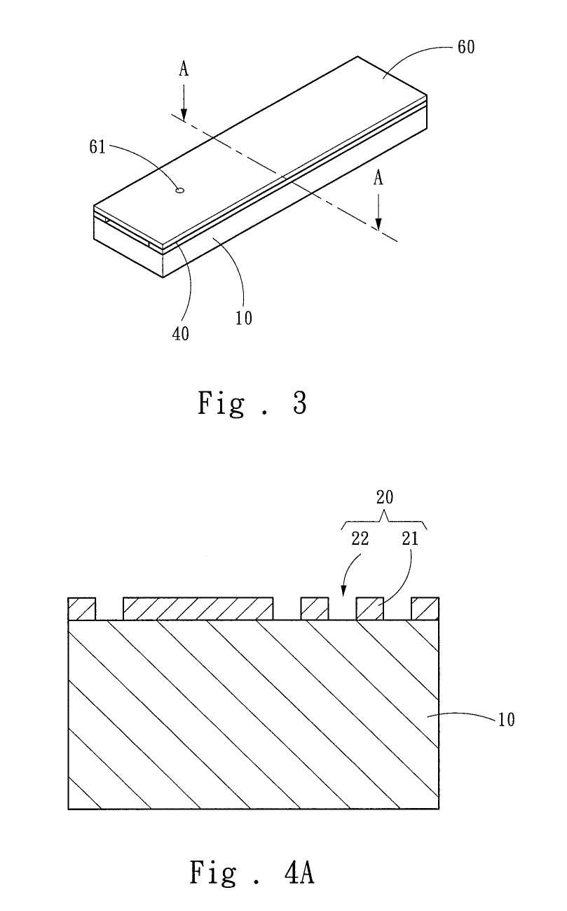

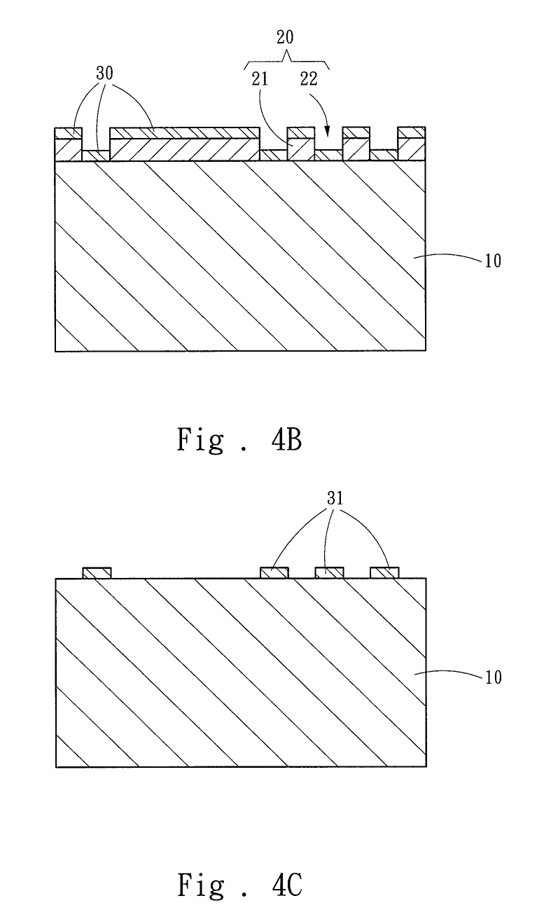

As shown in FIGS. 1 to 4C, the present invention relates to a biosensor test strip made in the process without the use of an etchant and its etchant-free fabrication method. FIGS. 4A to 4C are cross-sectional views taken along the line A-A in FIG. 3. The related fabrication method of the present invention comprises the steps of:

Step S1: Forming a patterned stripping layer 20 on a substrate 10 as shown in FIG. 4A. The patterned stripping layer 20 includes a masking region 21 and a hollow region 22 adjacent to the masking region 21 to expose the substrate 10. And the hollow region 22 defines a wiring pattern. The material of the substrate 10 can be polyethylene terephthalate (PET), polyethylene naphthalate (PEN), fiberglass sheets (FR4), polycarbonate (PC), triacetate cellulose (TAC) or the combination thereof. And the material of the patterned stripping layer 20 can be polyvinyl chloride (PVC), vinyl resin, vinyl chloride or the combination thereof. The method used to form the patterned stripping layer 20 can be screen printing, relief printing, gravure printing and structural imprinting, etc., but not limited to the above-identified techniques. The foregoing methods can be applied by a roll-to-roll or sheet-by-sheet process. In one preferred embodiment, step S1 comprises the steps of:

Step S1A: Coating a strippable adhesive on a screen (not shown in the drawings), and the strippable adhesive penetrates the screen onto the substrate 10.

Step S1B: Curing the strippable adhesive to form the patterned stripping layer 20 on the substrate 10. In one preferred embodiment, the thickness of the patterned stripping layer 20 is between 1 μm to 100 μm, and the patterned stripping layer 20 is comprised of the masking region 21 defined by the screen and the hollow region 22 adjacent to the masking region 21 to expose the substrate 10. And the hollow region 22 defines the wiring pattern. And the curing method for the strippable adhesive can be infrared light curing, ultraviolet light curing, etc., but not limited only thereto.

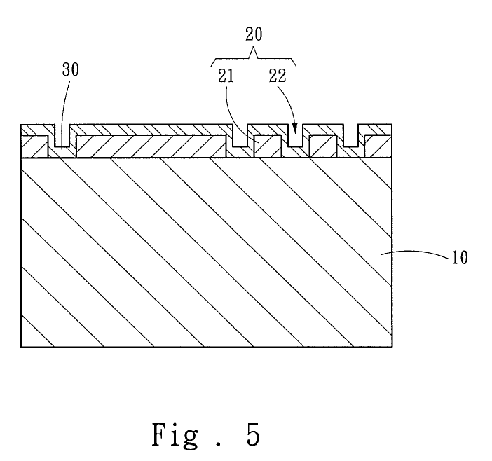

Step S2: Sputtering a metallic film 30 on the masking region 21 and the hollow region 22 of the patterned stripping layer 20 as shown in FIG. 4B. Since the substrate 10 is exposed in the hollow region 22, the sputtering is performed directly onto the substrate 10. The thickness of the metallic film 30 is between 5 nm and 900 nm and the material of the metallic film 30 can be gold, platinum, palladium, iridium, titanium, silver, nickel, copper, chromium, etc. In one preferred embodiment, as shown in FIG. 4B, the metallic film 30 is formed only on the surface of the masking region 21 and the hollow region 22. In another preferred embodiment as shown in FIG. 5, however, the metallic film 30 is formed in a layer structure, covering not only the top of the masking region 21 as well as the hollow region 22, but also the side walls.

Step S3: Washing off the patterned stripping layer 20 by a non-etchant liquid which is miscible with the patterned stripping layer 20. As a result, referring to FIG. 4C, the masking region 21 of the patterned stripping layer 20 and the metallic film 30 thereon are removed, and the metallic film 30 on the substrate 10 is remained so as to form a detection line 31 corresponding to the wiring pattern defined by the hollow region 22. The detection line 31 includes a working end 32 and a measuring end 33 away from the working end 32. In one preferred embodiment, the non-etchant liquid as mentioned above can be water, alkaline water or the combination thereof, but not limited thereto. Through this method, it is possible to avoid the chemical pollution caused by the use of the etchant and the problem of the residual etchant on the biosensor test strips. Further, a higher production efficiency with this liquid cleaning method can be achieved and the removed metallic film 30 in the non-etchant liquid can be recycled and reused in order to reduce the costs.

Step S3A: Removing the residual non-etchant liquid on the substrate 10 and the detection line 31 by an air knife so as to keep the substrate 10 and the detection line 31 dry to facilitate the subsequent processes.

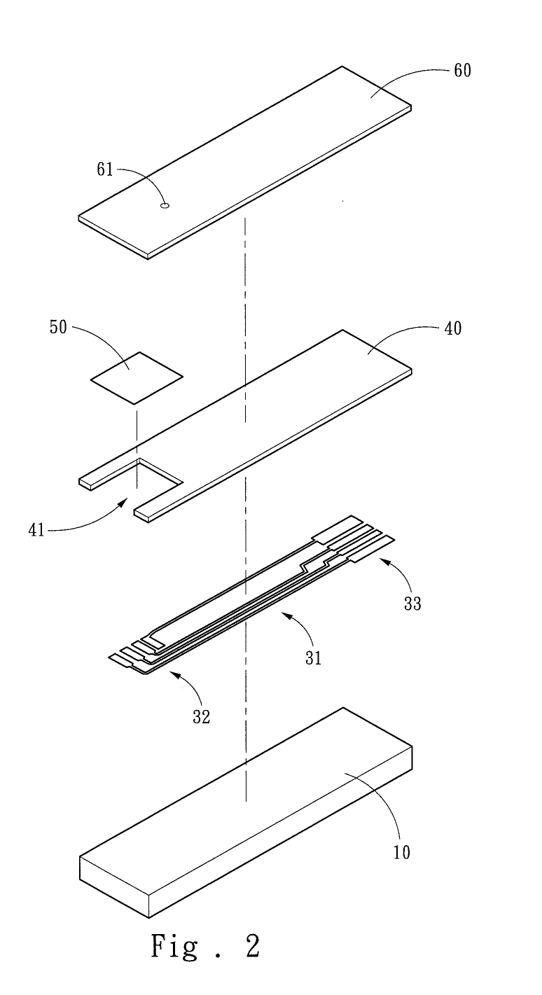

Step S4: Forming a pad layer 40 on the detection line 31 as well as the substrate 10 as shown in FIG. 2. The pad layer 40 includes an opening 41 for exposing the working end 32.

Step S5: Forming a reacting enzyme 50 in the opening 41, located on top of the working end 32.

Step S6: Forming an upper cover 60 on the pad layer 40. The upper cover 60 comprises an air hole 61 communicating with the opening 41 in order to discharge the air or gas located in the opening 41 and to allow the entry of a tested object. The present inventive biosensor test strip is formed in this step.

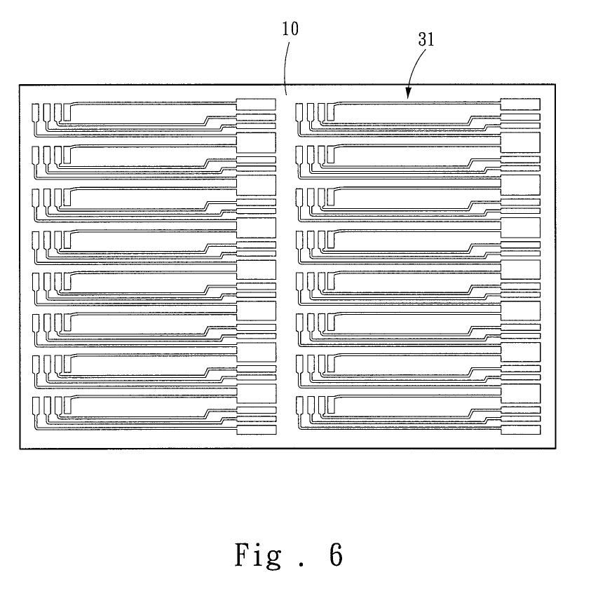

Turning to FIG. 6, in the production, a plurality of the detection lines 31 can be formed on the substrate 10 in an array format. On top of the arrayed detection lines 31, the pad layer 40, the reacting enzyme 50 and the upper cover 60 can be formed respectively. After the cutting, an individual biosensor test strip can be obtained.

In view of the foregoing, the present invention has the characteristics as follows:

1. Through the non-etchant liquid to wash off the patterned stripping layer, it is possible to avoid the chemical contamination caused by the etchant and the problem of the residual etching liquid on the biosensor test strips. And the liquid cleaning method of the present invention has a higher production efficiency. Further, the removed metallic film can be reused from the non-etchant liquid so as to reduce the costs.

2. Through the air hole provided, the air or gas in the opening can be discharged to facilitate the entry of a tested object.

What is claimed is:

1. An etchant-free fabrication method for producing a biosensor test strip, comprising the steps of:
S1: forming a patterned stripping layer on a substrate, wherein the patterned stripping layer comprises a masking region and a hollow region adjacent to the masking region to expose the substrate, and the hollow region defines a wiring pattern;
S2: sputtering a metallic film onto the masking region of the patterned stripping layer and the substrate below the hollow region;
S3: removing the masking region together with the metallic film thereon through a non-etchant liquid miscible with the patterned stripping layer, but leaving the metallic film on the substrate so as to form a detection line corresponding to the wiring pattern defined by the hollow region, wherein the detection line comprises a working end and a measuring end away from the working end;
S4: forming a pad layer onto the detection line and the substrate, wherein the pad layer comprises an opening to expose the working end; and
S5: forming a reacting enzyme in the opening.

2. The fabrication method as recited in claim 1, wherein, in step S1, the material of the substrate is selected from the group consisting of polyethylene terephthalate (PET), polyethylene naphthalate (PEN), fiberglass sheets (FR4), polycarbonate (PC), triacetate cellulose (TAC) and the combination thereof.

3. The fabrication method as recited in claim 1, wherein, in step S1, the material of the patterned stripping layer is selected from the group consisting of polyvinyl chloride (PVC), vinyl resin, vinyl chloride and the combination thereof.

4. The fabrication method as recited in claim 1, wherein, in step S3, the non-etchant liquid is selected from the group consisting of water, alkaline water and the combination thereof.

5. The fabrication method as recited in claim 1, wherein, in step S1, it further comprises the steps of:
S1A: coating a strippable adhesive on a screen, enabling the strippable adhesive to penetrate the screen onto the substrate; and
S1B: curing the strippable adhesive to form the patterned stripping layer on the substrate, wherein the patterned stripping layer is comprised of the masking region defined by the screen and the hollow region adjacent to the masking region to expose the substrate, and the hollow region defines the wiring pattern.

6. The fabrication method as recited in claim 5, wherein, in step S1B, the curing method for the strippable adhesive is selected from the group consisting of infrared light curing and ultraviolet light curing.

7. The fabrication method as recited in claim 1, wherein, after step S3, it further comprises the step of:
S3A: removing the residual non-etchant liquid on the substrate and the detection line by an air knife.

8. The fabrication method as recited in claim 1, wherein, after step S5, it further comprises the step of:
S6: forming an upper cover on the pad layer, wherein the upper cover comprises an air hole communicating with the opening.

9. The fabrication method as recited in claim 1, wherein, in step S1, the method used to form the patterned stripping layer is selected from the group consisting of screen printing, relief printing, gravure printing and structural imprinting.

10. A biosensor test strip which is produced by the fabrication method as recited in claim 1.
